(19) United States
(12) Patent Application Publication
(10) Pub. No.: US 2026/0334133 A1
(43) Pub. Date: Oct. 22, 2026

(54) WAFER PROCESSING APPARATUS

(71) Applicant: Hitachi High-Tech Corporation, Minato-ku, Tokyo (JP)

(72) Inventors: Masaki YAMADA, Tokyo (JP); Takahiro IWAI, Tokyo (JP)

(21) Appl. No.: 19/111,221

(22) PCT Filed: Sep. 27, 2023
(86) PCT No.: PCT/JP2023/035295

§ 371 Date: Mar. 12, 2025

(51) Int. Cl. H10P 72/00; H05B 3/00

(52) U.S. Cl. CPC H10P 72/0421; H05B 3/0047

(57) ABSTRACT

A wafer processing apparatus including a processing chamber; a sample stage; a gas introduction unit disposed above the sample stage and having a gas introduction port; and a lamp unit disposed around the gas introduction unit and constituting a ceiling of the processing unit. The lamp unit includes a plurality of ring-shaped lamps which are disposed in a multiplex manner around the gas introduction unit; and a reflecting member having a ring shape above the plurality of lamps around the gas introduction unit and which has a reflecting surface configured to allow the electromagnetic waves emitted from the plurality of lamps to be reflected downward and toward a central region of the processing chamber, the height of the reflecting surface being higher at a location close to the gas introduction unit and lower from the gas introduction unit toward the outer peripheral side.

### TECHNICAL FIELD

This invention relates to a wafer processing apparatus.

### BACKGROUND ART

In a semiconductor device, further miniaturization and three-dimensionalization of device structures are progressing due to the demand for lower power consumption and increased memory capacity. In the manufacture of devices with three-dimensional structures, since the structures are three-dimensional and complex, there has been a demand for “isotropic etching” which allows etching in a lateral direction as well in addition to the conventional “vertical etching” which performs etching in the direction perpendicular to a wafer surface.

As an example of a prior art which performs isotropic etching with high accuracy by dry processing, there has been known an adsorption/desorption type etching method described in Japanese Unexamined Patent Application Publication No. 2015-185594 (Patent Literature 1). In this prior art, radicals generated by plasma are first adsorbed onto the surface of a layer to be etched of an object to be treated placed on a stage arranged inside a processing chamber, and a reaction layer is formed by a chemical reaction (adsorbing process), and then thermal energy is applied to desorb and remove this reaction layer (desorbing process). Etching is performed by alternately and cyclically repeating such adsorbing and desorbing processes.

In this prior art, in order to apply the thermal energy to the surface of the object to be treated in the desorbing process, a lamp which radiates electromagnetic waves in an ultraviolet or infrared range is provided above the stage disposed within the processing chamber. In the desorbing process, the object to be treated is heated to a temperature at which the reaction layer on the surface of the layer to be etched is sublimed in a short time.

Further, in Japanese Unexamined Patent Application Publication No. 2020-097060 (Patent Literature 2), there is provided a stage disposed inside a processing chamber arranged inside a vacuum container. Ring-shaped IR lamps which irradiate electromagnetic waves in an infrared range (hereinafter referred to as infrared light or IR or IR light) arranged in a multiple manner around a flow path directly above the stage through which reactive particles such as radicals are supplied into the processing chamber, and a reflecting plate which is arranged above these IR lamps and reflects the IR light emitted from the IR lamps toward the upper surface of a wafer stage in the lower processing chamber or a wafer placed on the upper surface. With this configuration, in the present prior art, the wafer is irradiated with the IR light reflected by the reflecting plate together with the IR light directly emitted from the IR lamp, so that the wafer is heated in a short time.

### CITATION LIST

### Patent Literature

Patent Literature 1: Japanese Unexamined Patent Application Publication No. 2015-185594
Patent Literature 2: Japanese Unexamined Patent Application Publication No. 2020-097060

### SUMMARY OF INVENTION

### Technical Problem

As in the above-described prior art, particles (etchant) that make up reactive gases or vapors supplied into the processing chamber in the container are supplied downward from an introduction port located in the central portion of the processing chamber and disposed above the center of the upper surface of the sample stage on which the wafer is placed and supported. The etchant is deposited in contact with the upper surface of the wafer and reacts with the surface of a film to be treated in a film structure having a plurality of film layers including the film layer to be treated arranged in advance on the upper surface of the wafer. The amount of reaction and its magnitude distribution on the upper surface of the wafer are greatly affected by, for example, the balance between the amount of etchant supplied and the reaction temperature.

The amount of etchant supplied changes greatly depending on the reactive gas and vapor flow paths.

Therefore, in order to suppress variation in the amount of etchant in the radial or circumferential direction (in-plane direction) on the upper surface of the wafer, a configuration is preferred in which the etchant particles which reach the wafer moves from the center of the wafer toward the outer peripheral region, and then are exhausted from the space between the sample stage and the inner wall of the processing chamber around the sample stage, specifically, a configuration is preferred in which an exhaust is performed in a coaxial arrangement in which the opening of the gas introduction port, the center of the wafer, and the vertical central axis of the ring-shaped space located on the outer peripheral side of the sample stage and surrounding the outer peripheral side wall of the sample stage coincide with each other or are arranged in positions approximate to the same (coaxial exhaust). The above-described prior art has this coaxial exhaust configuration.

On the other hand, in the configuration of heating the wafer using IR (infrared) lamps in these prior arts, in order to ensure the heating speed thereof and the accuracy of the resulting temperature distribution, there is a demand for irradiation of the entire upper surface of the wafer with IR light set to a desired intensity and amount. However, in the above-described prior art, when the gas introduction port is disposed above the center of the wafer, the IR lamps cannot be disposed directly above the center of the wafer, and must be positioned around the gas introduction port. For this reason, in such a configuration, there is a risk that in adjusting the temperature of the central portion of the wafer, or the wafer temperature and its distribution in the in-plane direction of the wafer to a desired one, the accuracy thereof may be impaired. This may lead to variation in shape and a relative reduction in accuracy after etching processing in the central region, as compared with the outer peripheral portion of the upper surface of the wafer.

An object of the present invention is to provide a wafer processing apparatus which improves processing accuracy and yield.

### Solution to Problem

To achieve the above problem, the wafer processing apparatus includes: a processing chamber disposed inside a vacuum container; a sample stage which is disposed in a lower central portion in the processing chamber and on which a wafer to be processed is mounted and supported; a gas introduction unit disposed above a central portion of an upper surface of the sample stage and having a gas introduction port introducing a gas for processing the wafer into the processing chamber; and a lamp unit disposed around the gas introduction unit and constituting a ceiling of the processing unit. In the wafer processing apparatus, the lamp unit includes: a plurality of ring-shaped lamps which are disposed in a multiplex manner around the gas introduction unit, and irradiates the wafer on the sample stage with electromagnetic waves; and a reflecting member which is disposed to be a ring shape above the plurality of lamps around the gas introduction unit and has a reflecting surface configured to allow the electromagnetic waves emitted from the plurality of lamps to be reflected downward and toward a central region of the processing chamber, and in which the height of the reflecting surface is made higher at a location close to the gas introduction unit and is lowered from the gas introduction unit toward the outer peripheral side.

According to the present invention, it is possible to change the value of the temperature of a wafer and its distribution as desired by reflecting electromagnetic waves emitted from lamps in a predetermined direction above. This makes it possible to precisely control the temperature of the wafer during processing within a range suitable for processing, thereby improving processing yield.

### BRIEF DESCRIPTION OF DRAWINGS

FIG. 1 is a longitudinal sectional view schematically illustrating an outline of a configuration of a wafer processing apparatus according to an embodiment of the present invention.

FIG. 2 is a longitudinal sectional view schematically illustrating an outline of a configuration of a wafer processing apparatus according to a modification of the embodiment illustrated in FIG. 1.

FIG. 3 is a longitudinal sectional view schematically illustrating an outline of a configuration in the modification illustrated in FIG. 2 when reflecting surfaces of a plurality of movable reflecting plates are made parallel to an upper surface of a wafer, and a graph illustrating a temperature distribution in a radial direction of the upper surface of the wafer in this case.

FIG. 4 is a longitudinal sectional view schematically illustrating an outline of a configuration in the modification illustrated in FIG. 2 when the reflecting surfaces of the plurality of movable reflecting plates are inclined with respect to the upper surface of the wafer to reflect IR light toward the center of the wafer, and a graph illustrating a temperature distribution in the radial direction of the upper surface of the wafer in this case.

FIG. 5 is a graph illustrating an example of changes in the magnitude of intensities (illuminance) of IR direct light and IR reflected light at two IR lamps and reflecting plates and positions on a wafer W therebelow as an inclination angle of each reflecting surface of the reflecting plate changes, in the modification illustrated in FIG. 2.

FIG. 6 is a view schematically illustrating a model of the arrangement of an IR lamp unit used to calculate an example of the change in the intensity of the IR light illustrated in FIG. 5.

FIG. 7 is a graph illustrating an example of the distribution of the intensity (illuminance) of IR light in the radial direction of the upper surface of the wafer when the angle of the reflecting plate illustrated in FIG. 2 is inclined by a predetermined value.

### DESCRIPTION OF EMBODIMENTS

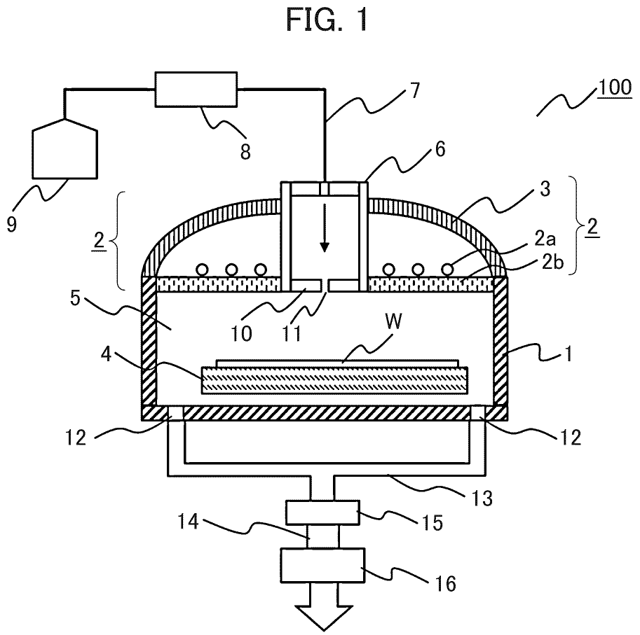

One embodiment of the invention will now be described with reference to the drawings. Hereinafter, an embodiment and a modification of the present invention will be described with reference to FIGS. 1 to 7.

FIG. 1 is a longitudinal sectional view schematically illustrating an outline of a configuration of a wafer processing apparatus according to an embodiment of the present invention. A wafer processing apparatus 100 of the present embodiment roughly includes a processing container whose interior can be depressurized, a gas supply section which is connected to an upper portion of the processing container and supplies a processing gas for processing a sample on a substrate such as a semiconductor wafer to be processed into the processing container, and an exhaust unit which is connected to a lower portion of the processing container and exhausts a gas inside the processing container. In the wafer processing apparatus 100, the processing container is an unillustrated vacuum container and is connected to a transport vessel through which a sample to be processed is transported within an internal space. A side wall of the processing container is provided with an unillustrated opening (gate) which Serves as a passage through which the sample passes inside between the interior of the transport vessel and the interior of the processing container.

The processing container includes a vacuum container 1 which is a metallic container and has a processing chamber 5 being a space having a cylindrical shape thereinside, and a sample stage 4 which is disposed underneath the interior of the processing chamber 5 and on whose upper surface a wafer W being a sample to be processed is placed and held or supported. Further, there is disposed a gas introduction unit 6 above the central portion of the processing chamber 5 and through which a gas for processing, dilution or cleaning supplied to the processing chamber 5 flows in a pipe-shaped or cylindrical internal space. The gas introduction unit 6 may be disposed above the central portion of the ceiling of the processing chamber 5. A lower end thereof may be exposed to the space inside the processing chamber 5 and constitute the ceiling of the processing chamber 5.

A gas introduction plate 10 having a disk shape made of a dielectric material is disposed at the lower end of the gas introduction unit 6. At the central portion of the gas introduction plate 10, there is disposed at least one gas introduction port 11 through which a gas such as a processing gas which has passed through the cylindrical space inside the gas introduction unit 6 is introduced toward the processing chamber 5 through the inside. In the present embodiment, the particles of the processing gas which has entered the processing chamber 5 through the gas introduction port 11 diffuse inside the processing chamber 5 and are deposited onto a film structure having multiple layers including a film layer to be processed and a film layer for a mask, which are disposed in advance on the upper surface of the wafer W placed on the upper surface of the sample stage 4. The deposited gas particles interact or react with the material at the surface of the film layer to be processed to form a desired product.

Further, a lamp unit 2 is provided which constitutes an upper portion of the vacuum container 1 and is disposed above the processing chamber 5 and surrounding an outer periphery of the gas introduction unit 6. The lamp unit 2 of the present embodiment is a lamp capable of irradiating infrared light (IR light) to the inside of the processing chamber 5 to heat the wafer W placed on the upper surface of the sample stage 4, and has multiple (three in the present figure) IR lamps 2a which surround the outer periphery of the gas introduction unit 6 and are disposed concentrically. Further, the lamp unit 2 is provided with a transmission window 2b which is a flat ring-shaped member made of a material capable of transmitting IR light and constitutes the top surface of the processing chamber 5 around the lower end of the gas introduction unit 6.

In addition, the lamp unit 2 in the present embodiment is provided with a cover dome 3 above each IR lamp 2a. The cover dome 3 is a plate-like member that surrounds the outer periphery of the gas introduction unit 6 and is disposed to cover the IR lamp 2a and the transmission window 2b, and has a curved shape in which the position of its central portion is made high and the position of its outer peripheral portion is made low. The cover dome 3 has a circular opening in its central portion and has a ring-like shape when viewed from above, and its inner peripheral edge is disposed so as to surround the outer periphery of the gas introduction unit 6. Furthermore, an outer surface and a lower surface (inner surface) of the cover dome 3 have a so-called dome-like shape in which they are inclined so as to become low from the central portion of the cover dome 3 toward its outer peripheral edge, and the angle of its inclination increases from the center toward the outer periphery.

Since the inner surface of the cover dome 3 has such a shape and is configured so that the inner surface can act as a reflecting surface which reflets the IR light emitted from the IR lamp 2a, at least a part of the IR light irradiated from the IR lamp 2a disposed in a ring shape is reflected at the inner surface of the cover dome 3 toward the center and downward of the processing chamber 5. That is, in the embodiment illustrated in the figure, the cover dome 3 is used as a reflecting member for IR light with its lower surface (inner surface) used as a reflecting surface. Thus, the IR light (IR reflected light) emitted from each IR lamp 2a and reflected by the inner wall surface of the cover dome 3 travels downward and toward the center of the upper surface of the stage 4, passes through gaps between the IR lamps 2a disposed in multiple ring shape and a gap between the gas introduction unit 6 and each IR lamp 2a, and is irradiated onto the central surface of the wafer W when the wafer W is placed above the upper surface of the sample stage 4.

That is, the IR light emitted upward from each IR lamp 2a is reflected by the inner surface of the cover dome 3, passes through a space closer to the center of the wafer W than each IR lamp 2a, and is irradiated onto the wafer W. Consequently, in the central region on the upper surface of the wafer W, in addition to the IR light (IR direct light) which arrives directly from the IR lamp 2a, more IR reflected light is irradiated than in the outer peripheral side region, and a greater intensity or amount of IR light is irradiated.

A lower portion of the vacuum container 1 is connected to an exhaust section including an exhaust pump 16 and an exhaust pipe 13 connected thereto. In the exhaust section, one end of the exhaust pipe 13 is connected to the bottom surface of the vacuum container 1, and the inside of the exhaust pipe 13 communicates with the inside of the processing chamber 5 via an exhaust port 12 disposed below the sample stage 4 and facing the lower portion of the processing chamber 5. In the exhaust section, a flow rate control valve 15 which controls the flow rate or speed of the exhaust gas from the processing chamber 5 flowing inside the exhaust pipe 13, is provided between the other end of the exhaust pipe 13 connected to the exhaust port 12 and an inlet of the exhaust pump 16. The flow rate control valve 15 and the exhaust pump 16 are connected by an exhaust pipe 14.

An upper end of the gas introduction unit 6 is connected to the gas supply section. The gas supply section includes a plurality of gas storage units 9 such as tanks in which gases are divided for each type and stored therein, a gas supply line 7 including piping having one end connected to each gas storage unit and the other end connected to the upper end of the gas introduction unit 6 and through the inside of which the gas from each gas storage unit flows, and a gas flow rate regulator 8 such as an MFC (mass flow controller) which is disposed on the gas supply line 7 between each gas storage unit 9 and the gas introduction unit 6 and adjusts the flow rate or speed of the gas flowing therethrough. The pressure inside the processing chamber 5 is adjusted to a value within a range suitable for processing, by balancing the flow rate per unit time of the gas introduced into the processing chamber 5 from the gas introduction port 11 and the flow rate per unit time of particles such as the gas from the processing chamber 5 exhausted through the exhaust port 12.

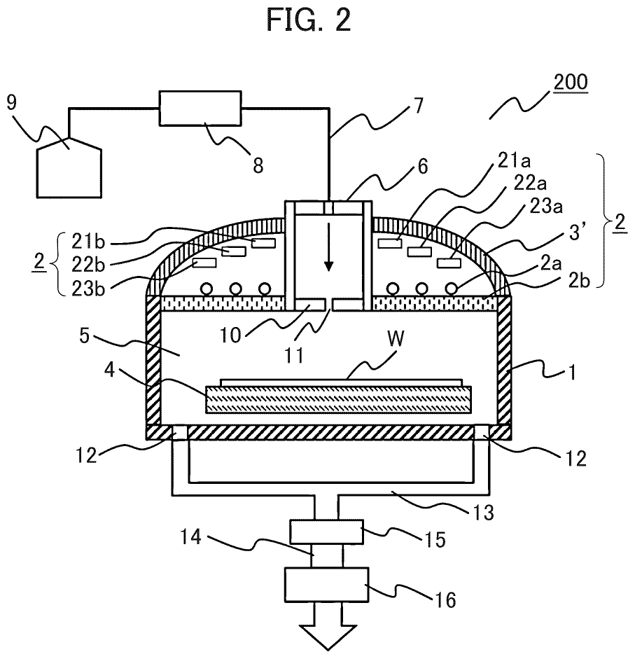

A modification of the embodiment of the present invention will be described with reference to FIG. 2.

FIG. 2 is a longitudinal sectional view schematically illustrating an outline of a configuration of a wafer processing apparatus according to a modification of the embodiment illustrated in FIG. 1. The difference between the embodiment illustrated in FIG. 1 and the modification illustrated in this figure resides in that a lamp unit 2 of a wafer processing apparatus 200 according to the modification includes a plurality of reflecting plate units 21, 22, and 23 configured so that reflecting plates have a plurality of flat plate-like shapes disposed in multiple concentric and ring shapes, above each of the IR lamps 2a disposed to have multiple concentric ring shapes, and a cover dome 3′ which is disposed on the outer peripheral side of the gas introduction unit 6, covers the reflecting plate units 21 to 23, the IR lamps 2a, and the transmission window 2b above the reflecting plate units 21 to 23, and has curved upper and lower surfaces with a high central portion and a low outer peripheral portion.

When each of the reflecting plate units 21, 22, and 23 in the present embodiment is viewed from above on a vertical axis (central axis) passing through the center of a wafer W or a sample stage 4 having a circular shape, a plurality of reflecting plates 21a, 21b, . . . , 22a, 22b, . . . , 23a, 23b, . . . made up of a plurality of square flat plate members and each having a surface (reflecting surface) capable of reflecting IR light are respectively disposed in a ring shape on a circumference at three different heights from the upper surface of the wafer W, at three radial positions of different lengths in the radial direction from the center. The surface (upper surface) opposite to the reflecting surface of each of the multiple reflecting plates 21a, 21b, . . . , 22a, 22b, . . . , 23a, 23b, . . . is connected to an angle adjustment mechanism disposed on the underside (inside) of the lower surface of the cover dome 3′, so that the reflecting surface of the IR light from the IR lamp 2a can be inclined toward the center of the processing chamber 5, the sample stage 4, or the wafer W.

In the present embodiment, the central points of the reflecting-plate reflecting surfaces of the reflecting plates 21a, 21b, . . . , 22a, 22b, . . . , 23a, 23b, which constitute each of the reflecting plate units 21, 22, and 23 as a plurality of sets are disposed at positions for each reflecting plate unit such that the radius from the central axis of the wafer W, the stage 4 or the processing chamber 5 matches with or is made closer enough to be regarded as the radius of each of the three IR lamps 2a each disposed in a ring shape. Further, the height from the upper surface of the wafer W at which the central points of the reflecting surfaces of the reflecting plates belonging to each of these three reflecting plate units 21 to 23 are disposed increases for each group of reflecting plates as they approach the center of the processing chamber 5, the sample stage 4, or the wafer W. That is, the central positions of the reflecting plates 21a, 21b, . . . are disposed at the highest position from the wafer W and are also located at the largest vertical distance from the IR lamp 2a.

In such a configuration, when the reflecting surfaces of the reflecting plates 21a, 21b, . . . , 22a, 22b, . . . , 23a, 23b, . . . of each reflecting plate unit 21, 22, 23 are inclined and held at a predetermined angle so that the reflected IR light (IR reflected light) is directed toward the center of the processing chamber 5, or the stage 4 or the upper surface of the wafer W, the reflected IR light (IR reflected light) each travels downward and toward the center of the upper surface of the wafer W, passes through the gaps between the IR lamps 2a disposed in multiple ring shape and the gaps between the IR lamps 2a and the gas introduction unit 6, and is irradiated onto the upper surface of the wafer W. That is, the IR light emitted upward from each IR lamp 2a is reflected by each reflecting plate unit 21, 22, 23, passes through a space closer to the center of the wafer W than each IR lamp 2a, and is irradiated onto the wafer W. Consequently, in the central region of the upper surface of the wafer W, in addition to the IR light (IR direct light) which arrives directly from the IR lamp 2a, more IR reflected light is irradiated than in the outer peripheral region, and IR light of greater intensity is irradiated.

On the other hand, when the above reflecting surface is held parallel to the upper surface of the wafer W, as in the above case, the upper surface of the wafer W is irradiated with the IR direct light together with the IR reflected light, but the intensity of the IR reflected light irradiated to the central region of the wafer W becomes relatively smaller than when the reflecting plates of each reflecting plate unit 21, 22, 23 are inclined so that the IR reflected light is directed toward the central side. Further, in the present embodiment, the lower end of the gas introduction unit 6 constitutes the center of the ceiling of the processing chamber 5. It is not possible to place the IR lamp above the center and irradiate the wafer W with a strong intensity obtained by making the IR direct light of the IR lamp 2a incident to the upper surface of the wafer W at an angle perpendicular to the upper surface of the wafer W or closer to this angle. Therefore, even in regard to the intensity and amount of the IR direct light, the intensity and amount thereof also become relatively smaller than that irradiated on the outer peripheral side.

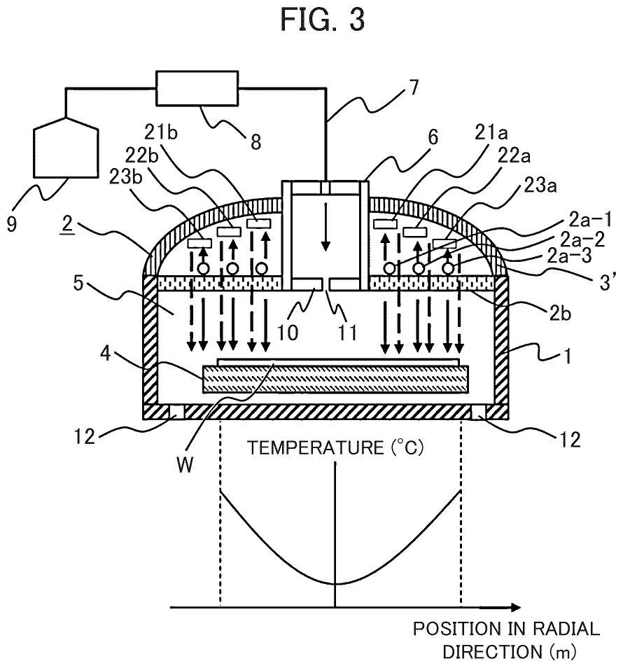

FIG. 3 is a graph schematically illustrating an example of the temperature distribution on a wafer obtained when the reflecting surface of the reflecting plate in the modification illustrated in FIG. 2 is held parallel to the sample stage or wafer. Incidentally, in the present figure, the IR direct light is indicated by an arrow of a solid line, and the IR reflected light is indicated by an arrow of a broken line. As described above, in the example illustrated in this figure, the IR direct light emitted downward from the lamp unit 2 is irradiated directly from the IR lamp 2a onto the upper surface of the wafer W located below. On the other hand, the IR light emitted upward from the IR lamp 2a becomes IR reflected light reflected so as to be downward by the reflecting surface of the reflecting plate of any of the reflecting plate units 21 to 23, passes through the gaps between the triple concentrically arranged ring-shaped IR lamps 2a, and is irradiated onto the upper surface of the wafer W below the gaps.

As described above, in the example illustrated in this figure, the intensity or amount of each of the IR direct light and the IR reflected light emitted from the lamp unit 2 becomes greater in the outer peripheral region of the wafer W compared to the central region thereof. Therefore, the temperature of the upper surface of the Wafer W is distributed so as to be relatively low in the central region and high in the outer peripheral region.

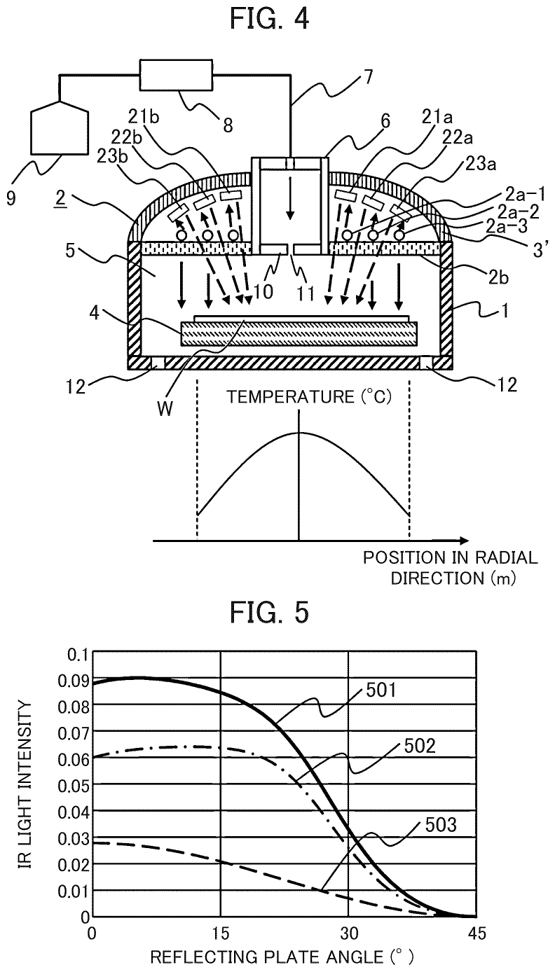

FIG. 4 is a graph schematically illustrating an example of the temperature distribution on the wafer obtained when the reflecting surface of the reflecting plate in the modification illustrated in FIG. 2 is held facing the center of the sample stage or the wafer. Incidentally, even in the present figure, IR direct light is indicated by an arrow of a solid line, and IR reflected light is indicated by an arrow of a broken line. As described above, in the example illustrated in this figure, the IR direct light emitted downward from the lamp unit 2 is irradiated directly from the IR lamp 2a onto the upper surface of the wafer W located below. On the other hand, the IR light emitted upward from the IR lamp 2a becomes IR reflected light reflected so as to be directed downward and toward the center of the wafer W at the reflecting surface of the reflecting plate of any of the reflecting plate units 21 to 23, passes through the gaps between the triple concentrically arranged ring-shaped IR lamps 2a, and is irradiated onto the upper surface of the wafer W below the gaps.

Further, the IR reflected light obtained when the IR light emitted upward from the IR lamp 2a-1 disposed on the innermost circumference is reflected downward and toward the central region of the wafer W by each of the reflecting plates 21a and 21b, . . . passes through the gap between the innermost IR lamp 2a-1 and the outer peripheral edge of the lower end of the gas introduction unit 6, and further travels toward the center of the wafer W so as to be irradiated onto the upper surface of the wafer W. As described above, in addition to the configuration in which the transmission window 2b is made of a material which can transmit IR light, the lower end of the cylindrical side wall of the gas introduction unit 6 or the gas introduction plate 10 may be made of a material which can transmit IR light. In this case, the IR reflected light reflected by at least any of the reflecting plate units 21 to 23 is irradiated with a greater intensity or amount onto the central portion of the wafer W in which the intensity or amount of the IR direct light is small, through the gas introduction unit 6 which constitutes the central portion of the ceiling of the processing chamber 5. For this reason, the intensity or amount of the IR reflected light becomes greater in the central region of the wafer W compared to the outer peripheral region thereof, and the temperature of the upper surface of the wafer W is distributed so that the temperature is relatively higher in the central region and lower in the outer peripheral region.

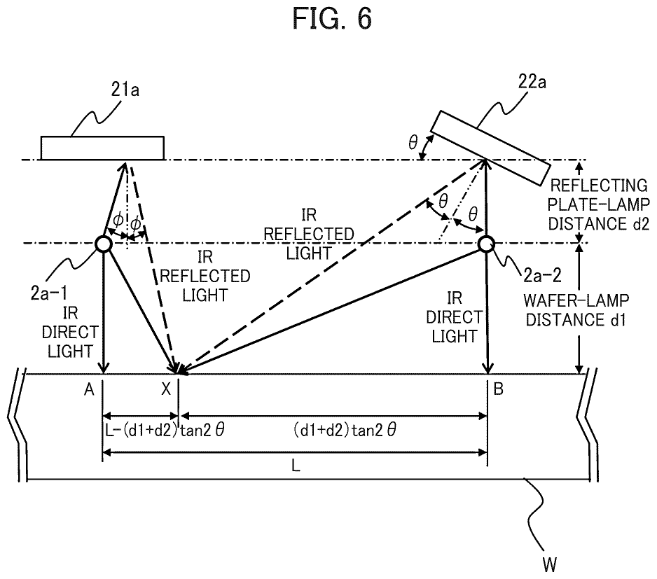

An example of changes in the degree of inclination of the reflecting surface of the reflecting plate of the lamp unit 2 and the magnitude of intensities (illuminance) o f the IR direct light and the IR reflected light from the IR lamp 2a in the modification illustrated in FIG. 2 will be described with reference to FIGS. 5 and 6. FIG. 5 is a graph illustrating an example of changes in the magnitude of intensities (illuminance) of the IR direct light and the IR reflected light at two IR lamps and a reflecting plate and at a position on the wafer W therebelow with the change in the inclination angle of the reflecting surface of the reflecting plate, in the modification illustrated in FIG. 2. FIG. 6 is a graph illustrating an example of the distribution of the intensity (illuminance) of the IR light in the radial direction of the upper surface of the wafer when the angle of the reflecting plate illustrated in FIG. 2 is made parallel to the wafer and when the angle of the reflecting surface of the reflecting plate is inclined by a predetermined value.

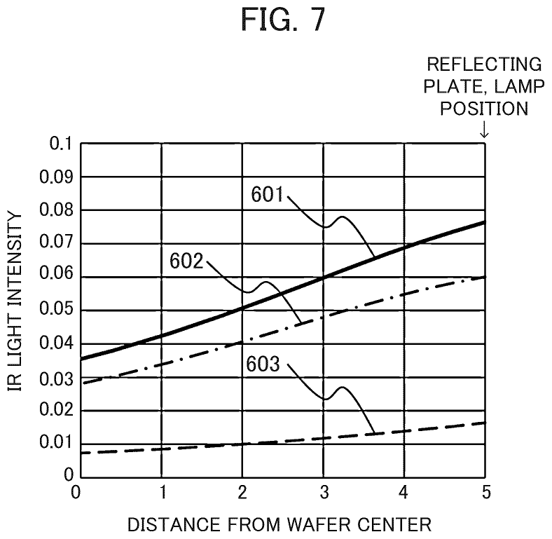

In FIGS. 5 and 7, as a model, there was used one in which conditions including the arrangement of the lamp unit 2 and the wafer W and the relative positional relationship were appropriately set. Under the conditions, a change in the intensity of the IR light was calculated. FIG. 6 is a view schematically illustrating a model of the arrangement of an IR lamp unit used to calculate the example of the change in the intensity of the IR light illustrated in FIG. 5.

In FIG. 6, at a position above the wafer Wat a height (distance) dl above the upper surface of the wafer W (in the vertical direction in the figure), two IR lamps 2a-1 and 2a-2 are disposed apart by a distance L in the horizontal direction (left and right direction in the figure). Further, the reflecting plates 21a and 22a are disposed above the IR lamps 2a-1 and 2a-2, respectively, at a distance (height) d2 spaced apart therebetween. In the present figure, the IR lamp 2a-1 on the left side of the figure corresponds to one on the innermost peripheral side in the radial direction from the center of the processing chamber 5, of the IR lamps 2a disposed in the triple ring shape in FIG. 2. The IR lamp 2a-2 on the right side of the figure is one for the second position in the radial direction. The reflecting plates 21a and 22a located above these belong to the reflecting plate units 21 and 22, respectively.

With respect to the wafer W located below these IR lamps 2a-1 and 2a-2 and reflecting plates 21a and 22a, the distance between points A and B on the wafer W projected vertically downward from above is defined as L. In such an arrangement illustrated in the present figure, when the reflecting plate 21a holds its reflecting surface parallel to the wafer W, and the angle θ at which the reflecting plate 22a inclines its reflecting surface relative to the horizontal direction (plane) is changed within a predetermined range, the total intensity of the IR direct light from the IR lamps 2a-1 and 2a-2 and the IR reflected light from the reflecting plates 21a and 22a at a location (position) X where the IR reflected light obtained by reflecting the IR direct light emitted directly upward from the IR lamp 2a-2 by the reflecting plate 22a is irradiated onto the wafer W is calculated.

In FIG. 5, reference numeral 502 indicates the change in the total intensity of IR direct light from the IR lamps 2a-1 and 2a-2, reference numeral 503 indicates the change in the total intensity of IR reflected light from the reflecting plates 21a and 22a, and reference numeral 501 indicates the change in the sum of the total intensity 502 of the IR direct light and the total intensity 503 of the IR reflected light. In the example of this figure, the calculations are conducted assuming that as an arbitrary unit of size, the distance L is 5, the height d1 is 5, and the height d2 is 0.1. It is shown that as the inclination angle of the reflecting plate 22a increases, the position X moves away from a position B, and the intensity 501 of the IR light at the position X initially increases slightly and then decreases. In particular, it is shown in the example of this figure that the intensity 501 of the IR light becomes the maximum under the condition that the inclination angle of the reflecting plate 22a with the position X located between the positions A and B in FIG. 6 is small.

FIG. 7 illustrates the change in IR light intensity with respect to the change in distance from the center of the wafer W when the IR lamp 2a and the reflecting plate thereabove are placed above a specific position in the radial direction from the center of the wafer W, and the angle of the reflecting surface is set to a predetermined value. In this figure, the IR lamp 2a is located in a position at a right-end distance on the graph. Reference numeral 602 indicates the change in the intensity of the IR direct light from the IR lamp 2a, reference numeral 603 indicates the change in the intensity of the IR reflected light from the reflecting plate above the IR lamp 2a, and reference numeral 601 indicates the change in the sum of the intensity 602 of the IR direct light and the intensity 603 of the IR reflected light. In this figure, it can be seen that as the position in the radial direction from the center on the wafer W approaches the point of projection from above the IR lamp 2a, the intensity 602 of the IR direct light and the intensity 603 of the IR reflected

As a result of the above-described investigations, the present inventors can obtain findings that in the embodiment and modifications illustrated in FIGS. 1 and 2, the cover dome 3 as the reflecting plate having the dome shape and the multiple reflecting plate units 21 to 23 arranged in the ring shape along the circumferences of different radii above each of the IR lamps 2a are used to make it possible to form the temperature distribution in which the temperature in the central portion of the wafer W is higher than that in the outer peripheral region. Further, it is envisioned that the temperature value and its distribution of the wafer W can be made as desired including the so-called center-high and outer-high temperature by variably adjusting the angles of the reflecting surfaces of the above reflecting plate units 21 to 23 within a positive and negative range with the state in which the angle is parallel to the wafer W being 0°.

In changing the temperature distribution of the wafer W in this way, the angle adjustment mechanism to which each reflecting plate of the reflecting plate units 21 to 23 is attached has the function of changing the angle at which the reflecting surface faces the wafer W or the stage 4 or the region toward the center of the processing chamber 5 or on its central portion side to the angle toward the outer peripheral regions of these, for example, the inner peripheral side wall of the processing chamber 5, and the angle can be independently adjusted to a different angle by each of the reflecting plate units 21 to 23. The angles of such reflecting plate units 21 to 23 are detected by a control unit which sends command signals to adjust the operation of each part of the wafer processing apparatuses 100 and 200 which are not illustrated in FIGS. 1 and 2, in response to outputs from a plurality of temperature sensors arranged inside the stage 4, and are adjusted by sending a signal to the angle adjustment mechanism depending on whether the temperature value or distribution of the wafer W differs from the target one.

As described in the above embodiment and modifications, in the present embodiment and modifications, the temperature value and its distribution during processing of the wafer W suitable for processing are obtained by supplying a greater intensity or amount of IR reflected light from the lamp unit 2 to the central side of the wafer, or irradiating the IR reflected light reflected by each reflecting plate of the reflecting plate units 21, 22, and 23, the angles of which is appropriately adjusted in the lamp unit 2, onto the desired region of the wafer W. This improves the processing accuracy and yield of the wafer W processed in each of the wafer processing apparatuses 100 and 200.

### LIST OF REFERENCE SIGNS

1: vacuum container
2: lamp unit
2a: IR lamp
2b: transmission window
3: cover dome
4: sample stage
5: processing chamber
6: gas introduction unit
7: gas supply line
8: gas flow rate regulator
9: gas storage unit
10: gas introduction plate
11: gas introduction port
12: exhaust port
13, 14: exhaust pipe
15: flow rate control valve
16: exhaust pump
21, 22, 23: reflecting plate unit
21a, 21b. 22a, 22b, 23a, 23b: reflecting plate
100, 200: wafer processing apparatus

1. A wafer processing apparatus comprising:
a processing chamber disposed inside a vacuum container;
a sample stage which is disposed in a lower central portion in the processing chamber and on which a wafer to be processed is mounted and supported;
a gas introduction unit disposed above a central portion of an upper surface of the sample stage and having a gas introduction port introducing a gas for processing the wafer into the processing chamber; and
a lamp unit disposed around the gas introduction unit and constituting a ceiling of the processing unit, wherein
the lamp unit includes:
a plurality of ring-shaped lamps which are disposed in a multiplex manner around the gas introduction unit, and irradiates the wafer on the sample stage with electromagnetic waves; and
a reflecting member which is disposed to be a ring shape above the plurality of lamps around the gas introduction unit and has a reflecting surface configured to allow the electromagnetic waves emitted from the plurality of lamps to be reflected downward and toward a central region of the processing chamber, and in which the height of the reflecting surface is made higher at a location close to the gas introduction unit and is lowered from the gas introduction unit toward the outer peripheral side.

2. The wafer processing apparatus according to claim 1, wherein
the reflecting surface of the reflecting member is constituted of a curved surface whose height is lowered from a central end to an outer peripheral end thereof.

3. The wafer processing apparatus according to claim 1, wherein
the lamp unit includes a plurality of flat reflecting plates disposed below the reflecting member and disposed in ring shapes around the center of the sample stage when viewed from above around the gas introduction unit, and the electromagnetic waves reflected by the plurality of reflecting plates are irradiated onto the wafer on the sample stage through a gap between the plurality of lamps or a gap between the lamp and the gas introduction unit.

4. The wafer processing apparatus according to claim 3, wherein
the lamp unit includes a plurality of reflecting plate units which are comprised of the plurality of reflecting plates at a plurality of different radial positions from the center of the sample stage around the center of the sample stage as viewed from above around the gas introduction unit.

5. The wafer processing apparatus according to claim 4, wherein
the plurality of reflecting plate units each include the plurality of reflecting plates constituting the respective units at different heights from the upper surface of the sample stage.

6. The wafer processing apparatus according to claim 3, comprising
an angle variable mechanism which variably adjusts the angle at which each of the reflecting surfaces of the plurality of reflecting plates is inclined relative to a horizontal plane, and adjusts each inclination angle of the plurality of reflecting plates so as to reflect the electromagnetic waves toward the central side or outer peripheral side of the sample stage.

7. The wafer processing apparatus according to claim 4, comprising
an angle variable mechanism which variably adjusts the angle at which each of the reflecting surfaces of the plurality of reflecting plates is inclined relative to a horizontal plane, and adjusts each inclination angle of the plurality of reflecting plates so as to reflect the electromagnetic waves toward the central side or outer peripheral side of the sample stage.

8. The wafer processing apparatus according to claim 5, comprising
an angle variable mechanism which variably adjusts the angle at which each of the reflecting surfaces of the plurality of reflecting plates is inclined relative to a horizontal plane, and adjusts each angle of the plurality of reflecting plates so as to reflect the electromagnetic waves toward the central side or outer peripheral side of the sample stage.

9. The wafer processing apparatus according to claim 6, further comprising:
a function of realizing, during processing of the wafer, both a distribution in which the temperature of the wafer is lower in the central region and higher in the outer peripheral region, and a distribution in which the temperature of the wafer is higher in the central region and lower in the outer peripheral region.

10. The wafer processing apparatus according to claim 7, further comprising:
a function of realizing, during processing of the wafer, both a distribution in which the temperature of the wafer is lower in the central region and higher in the outer peripheral region, and a distribution in which the temperature of the wafer is higher in the central region and lower in the outer peripheral region.

11. The wafer processing apparatus according to claim 8, further comprising:
a function of realizing, during processing of the wafer, both a distribution in which the temperature of the wafer is lower in the central region and higher in the outer peripheral region, and a distribution in which the temperature of the wafer is higher in the central region and lower in the outer peripheral region.
